(19) United States
(12) Patent Application Publication
(10) Pub. No.: US 2013/0148093 A1
(43) Pub. Date: Jun. 13, 2013

(54) HOLDING APPARATUS, DRAWING APPARATUS, AND METHOD OF MANUFACTURING ARTICLE

(71) Applicant: CANON KABUSHIKI KAISHA, Tokyo (JP)

(72) Inventor: Hiroshi Kii, Utsunomiya-shi (JP)

(73) Assignee: CANON KABUSHIKI KAISHA, Tokyo (JP)

(21) Appl. No.: 13/711,286

(22) Filed: Dec. 11, 2012

(30) Foreign Application Priority Data
Dec. 13, 2011 (JP) 2011-272504

(51) Int. Cl. H01J 37/20; H01L 21/683

(52) U.S. Cl. CPC H01J 37/20; H01L 21/683
USPC 355/72; 355/77; 269/20

(57) ABSTRACT

A holding apparatus holds a substrate. The apparatus includes a base having burls that support the substrate. A top surface of the base is configured such that a capillary pressure of a liquid provided in a gap between the base and the substrate supported by the burls increases with reduction in an amount of the liquid in the gap.

### BACKGROUND OF THE INVENTION

1. Field of the Invention

The present invention relates to a holding apparatus that holds a substrate.

2. Description of the Related Art

Extreme-ultraviolet (EUV) exposure apparatuses and electron-beam exposure (drawing) apparatuses that have been under development as next-generation semiconductor exposure apparatuses perform exposure on substrates in vacuums. In a vacuum, heat transfer caused by convection does not occur, and heat therefore tends to be accumulated in an object. Hence, it is important in the development of the above exposure apparatuses to provide measures for dealing with heat (measures for cooling the object).

In a case where a substrate to be subjected to exposure is cooled, a method is employed in which heat transfer from the substrate to a substrate holding member (hereinafter also simply referred to as holding member) is promoted by using a gas contained between the substrate and the holding member. In a substrate holding apparatus (hereinafter also simply referred to as holding apparatus) disclosed by International Publication No. 2009/011574, since an enhanced promotion of heat transfer is desired for improvement of resolving power and overlay precision, a liquid is contained between a substrate and a holding member, whereby the substrate is held on the holding member. Specifically, a layer of the liquid has a negative pressure, as a capillary pressure of the liquid, with respect to a vacuum atmosphere. This phenomenon is utilized in holding the substrate on the holding member.

In the holding apparatus disclosed by International Publication No. 2009/011574, since the liquid evaporates quickly in a vacuum, the force for holding the substrate is reduced with the quick evaporation of the liquid. If the above-mentioned negative pressure is constant, the holding force is proportional to the area of contact between the substrate and the liquid. When the area of contact is reduced with the progress of evaporation, the holding force is reduced. Hence, in the holding apparatus disclosed by International Publication No. 2009/011574, it may be difficult to maintain the holding force at a required level over a required period of time (for example, a period of time required for performing processes such as exposure (drawing) on the substrate that is held by the holding apparatus).

### SUMMARY OF THE INVENTION

The present invention provides, for example, a holding apparatus advantageous in terms of holding of a tolerable holding force thereof.

According to one aspect of the present invention, there is provided a holding apparatus that holds a substrate. The apparatus includes a base having burls that support the substrate. A top surface of the base is configured such that a capillary pressure of a liquid provided in a gap between the base and the substrate supported by the burls increases with reduction in an amount of the liquid in the gap.

Further features of the present invention will become apparent from the following description of exemplary embodiments with reference to the attached drawings.

### BRIEF DESCRIPTION OF THE DRAWINGS

FIG. 1 illustrates an exemplary substrate holding apparatus according to a first embodiment of the present invention.

FIG. 2 illustrates the principle of a configuration according to the first embodiment.

FIG. 3 illustrates an exemplary substrate holding apparatus according to a second embodiment of the present invention.

FIG. 4 illustrates an exemplary drawing apparatus according to either of the embodiments.

### DESCRIPTION OF THE EMBODIMENTS

Embodiments of the present invention will now be described with reference to the attached drawings. Basically, like elements are denoted by like reference numerals in all the drawings, and redundant description thereof is omitted.

### First Embodiment

The substrate holding apparatus according to the present invention is applicable to a drawing apparatus that performs drawing on a substrate with a charged particle beam, as described below, and to a wide variety of other apparatuses. FIG. 4 illustrates a drawing apparatus 10 according to either of the following embodiments of the present invention. The drawing apparatus 10 described herein employs an electron beam as a charged particle beam. The drawing apparatus 10 may alternatively employ any of other charged particle beams such as an ion beam. The drawing apparatus 10 includes a vacuum chamber 5, an electron optical system 3, and a stage 4. The electron optical system 3 and the stage 4 are housed in the vacuum chamber 5. The drawing apparatus 10 performs drawing on a substrate 2 with an electron beam and in a vacuum. The stage 4 is movable and positions the substrate 2 with respect to the electron optical system 3. The stage 4 includes a substrate holding apparatus 1 (hereinafter also simply referred to as holding apparatus) that holds the substrate 2.

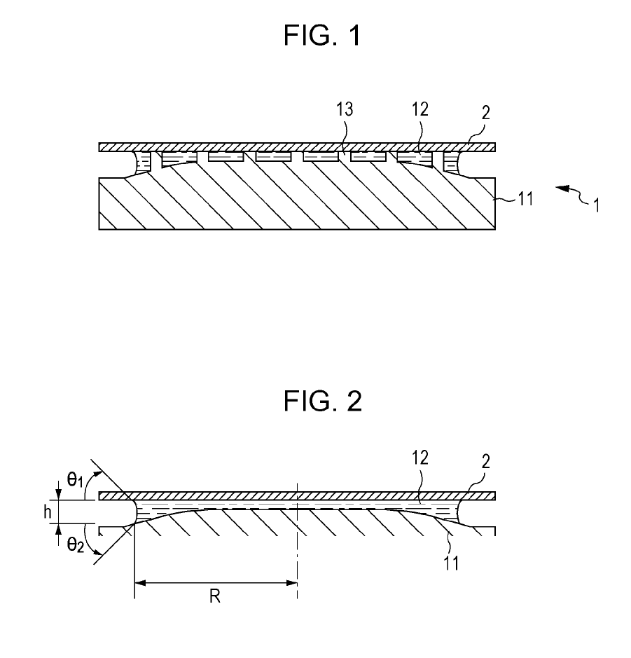

FIG. 1 illustrates the substrate holding apparatus 1 according to a first embodiment of the present invention. The substrate holding apparatus 1 includes a base 11 having burls (supporting portions) 13 that support the substrate 2. The substrate holding apparatus 1 may include a supply mechanism (not illustrated) that supplies liquid 12 into a gap between the substrate 2 and the base 11. An outward force is applied to the surface of the liquid 12 illustrated in FIG. 1 because of capillarity (the capillary pressure of the liquid 12). Therefore, the substrate 2 is pressed against the base 11 with a pressure (differential pressure) corresponding to the difference between the atmospheric pressure in the vacuum chamber 5 and the pressure of the liquid 12. With the differential pressure, a frictional force is produced between the substrate 2 and the burls 13, whereby the substrate 2 is prevented from sliding and is held on the base 11. The top surface of the base 11 (portions of the top surface of the base 11 excluding the burls 13) is formed such that the distance (gap) between the base 11 and the substrate 2 in an area of the base 11 that is in contact with the liquid 12 is reduced from the periphery (peripheral part) of the area toward the center (central part) of the area.

Referring to FIG. 2, the principle of the configuration according to the first embodiment will be described. A substrate holding force P per unit area of contact between the substrate 2 and the liquid 12 is expressed as follows:

P=γ×(cos θ₁+cos θ₂)/h (1)

where γ denotes the surface tension of the liquid 12, θ₁ denotes the angle of contact between the substrate 2 and the liquid 12, θ₂ denotes an angle formed between the interface between the liquid 12 and the top surface of the base 11 and a plane extending parallel to the substrate 2, and h denotes the distance from the interface between the liquid 12 and the substrate 2 to the interface between the liquid 12 and the base 11. The area of contact between the substrate 2 and the liquid 12 is expressed as π×R², where R denotes the radius of a layer of the liquid 12.

A substrate holding force F is the product of the substrate holding force P per unit area of contact expressed as Expression (1) and the area of contact π×R² between the substrate 2 and the liquid 12 and is expressed as follows:

F=P×π×R²=γ×(cos θ₁+cos θ₂)/h×π×R⁷ (2)

The top surface of the base 11 is formed such that the distance to the substrate 2 is reduced from the periphery thereof toward the center thereof. Hence, when the liquid 12 evaporates, the distance between the top surface of the base 11 and the substrate 2 at the periphery or an interface of the layer of the liquid 12 is reduced. That is, when R is reduced, h is reduced. Hence, even if the area of contact between the substrate 2 and the liquid 12 is reduced because of the evaporation of the liquid 12 or the like, the extent of reduction in the substrate holding force F is smaller than in a case where h is constant.

To suppress the reduction in the substrate holding force F, a configuration in which R²/h is constant or increases while R is reduced may be employed. In the first embodiment, θ₂ is constant (or the amount of change in θ₂ relative to the amount of change in R is sufficiently small). In general, θ₂ depends on the shape of the top surface of the base 11, that is, θ₂ is a function of R.

### Second Embodiment

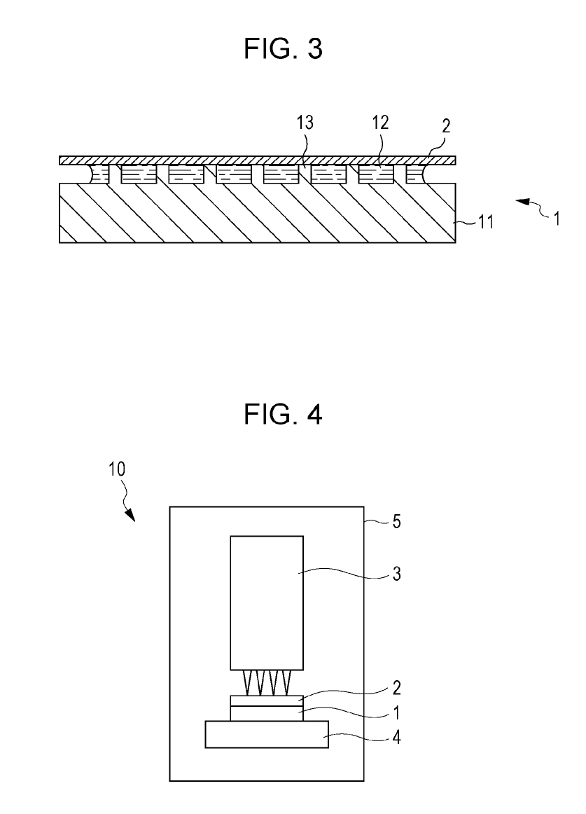

FIG. 3 illustrates a substrate holding apparatus 1 according to a second embodiment of the present invention. Unlike the configuration illustrated in FIG. 1, in the configuration illustrated in FIG. 3, the top surface of the base 11 is not formed such that the distance (gap) between the base 11 and the substrate 2 is reduced from the periphery thereof toward the center thereof. Instead, a portion of the top surface of the base 11 that is in contact with the liquid 12 is surface-treated or processed such that the angle of contact with the liquid 12 is reduced (the lyophilic character (the hydrophilic character if the liquid 12 is water) increases) from the periphery thereof toward the center thereof. In such a configuration, when R is reduced, (cosθ₁+cosθ₂) increases. Hence, even if the area of contact between the substrate 2 and the liquid 12 is reduced because of the evaporation of the liquid 12 or the like, the extent of reduction in the substrate holding force F is smaller than in a case where (cosθ₁+cosθ₂) is constant. The bottom surface of the substrate 2 may also be surface-treated or processed such that the angle of contact with the liquid 12 is reduced from the periphery thereof toward the center thereof.

To suppress the reduction in the substrate holding force F, a configuration in which (cosθ₁+cosθ₂)×R² is constant or increases while R is reduced may be employed.

### Third Embodiment

A method of manufacturing an article according to a third embodiment of the present invention is suitable for manufacturing articles such as microdevices, including semiconductor devices, and devices having microstructures. The method includes forming a latent pattern in a photoresist on a substrate (performing drawing on a substrate) by using the above drawing apparatus, and developing the latent pattern thus formed on the substrate. The method further includes other known steps (oxidization, film formation, vapor deposition, doping, planarization, etching, resist stripping, dicing, bonding, packaging, and so forth). The method of manufacturing an article according to the third embodiment is superior to known methods in terms of at least one of the performance, the quality, the ease of production, and the costs of production of the article.

While several embodiments of the present invention have been described above, the following exemplary modifications and changes can be made thereto. In each of the above embodiments, the top surface of the base 11 (and the bottom surface of the substrate 2) is configured such that the gap between the base 11 and the substrate 2 or the angle of contact between the substrate 2 and the liquid 12 is reduced from the periphery thereof toward the center thereof. In a case where the liquid 12 is contained in a plurality of dispersed areas defined in the gap between the substrate 2 and the base 11, the top surface of the base 11 (and the bottom surface of the substrate 2) may also be configured as described above in each area of the base 11 that is in contact with the liquid 12 provided in the gap.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-272504 filed Dec. 13, 2011, which is hereby incorporated by reference herein in its entirety.

What is claimed is:

1. A holding apparatus that holds a substrate, the apparatus comprising:
a base having burls that support the substrate,
wherein a top surface of the base is configured such that a capillary pressure of a liquid provided in a gap between the base and the substrate supported by the burls increases with reduction in an amount of the liquid in the gap.

2. The apparatus according to claim 1, wherein a portion, to be contacted with the liquid in the gap, of the top surface of the base is formed such that the gap is reduced from a peripheral part of the portion toward a central part of the portion.

3. The apparatus according to claim 1, wherein a portion, to be contacted with the liquid in the gap, of the top surface of the base is configured such that an angle of contact of the liquid relative to the top surface is reduced from a peripheral part of the portion toward a central part of the portion.

4. A drawing apparatus that performs drawing on a substrate with a charged particle beam, the apparatus comprising:
a holding apparatus defined in claim 1 that holds the substrate.

5. A method of manufacturing an article, the method comprising:
performing drawing on a substrate by use of a drawing apparatus;
developing the substrate on which the drawing has been performed; and
processing the developed substrate into the article,
wherein the drawing apparatus performs the drawing on the substrate with a charged particle beam, the apparatus including a holding apparatus that holds the substrate, the holding apparatus including:
a base having burls that support the substrate,
wherein a top surface of the base is configured such that a capillary pressure of a liquid provided in a gap between the base and the substrate supported by the burls increases with reduction in an amount of the liquid in the gap.
